(19) United States
(12) Patent Application Publication
(10) Pub. No.: US 2025/0094369 A1
(43) Pub. Date: Mar. 20, 2025

(54) METHOD AND ARRANGEMENT FOR ASCERTAINING A SEQUENCE OF STRUNG-TOGETHER COMMUNICATION-CAPABLE MODULES

(71) Applicant: Weidmüller Interface GmbH & Co. KG, Detmold (DE)

(72) Inventor: Gorm ROSE, Paderborn (DE)

(21) Appl. No.: 18/884,348

(22) Filed: Sep. 13, 2024

(30) Foreign Application Priority Data
Sep. 14, 2023 (DE) 102023124841.3

(51) Int. Cl. G06F 13/20

(52) U.S. Cl. CPC G06F 13/20; G06F 2213/40

(57) ABSTRACT

A method of ascertaining a sequence in which at least three strung-together communication-capable modules are arranged is provided. The method includes the steps of: outputting a magnetic signal from a first of module with a predefined intensity; increasing the intensity of the signal until the signal is detected by a module which is immediately adjacent to the transmitting module but not detected by a module which is not immediately adjacent to the transmitting module; outputting identification data through the module which has detected the magnetic signal via a communication channel to a determining unit; and determining a sequence of the modules by the identification data. An arrangement of at least three communication-capable modules able to be strung together, which each have a coil for outputting and/or receiving a magnetic signal, and have a determining unit is constructed to perform this method.

### BACKGROUND

The invention relates to a method of ascertaining a sequence in which at least three strung-together communication-capable modules are arranged. The invention also relates to an arrangement of at least three communication-capable modules which can be strung together and with which such a method can be performed.

In electrical installation and automation technology, arrangements of strung-together communication-capable modules are frequently employed. One example from automation technology are so-called ‘remote I/O’ systems; i.e. systems for the inputting and outputting of signals and/or data that are arranged remote from a control device, such as in a switch cabinet. These systems usually include a head module, also referred to as a head station, which establishes a connection to the control system, and several I/O (input/output) modules, which are strung onto the head module. For this purpose, the modules each have a top-hat rail receptacle and usually additional latching mechanisms for mechanical connection to a neighboring module.

With mechanical stringing-on, electrical connections can also be established between the modules which serve to establish a power supply bus and/or to establish a data bus between the modules and head station. Even if it required for the functionality of the bus system, it may be of interest for additional services to obtain information about a sequence in which the modules are strung together. For example, this information can be used to simplify troubleshooting on the I/O system, as the physical position of a faulty module can be visualized if the sequence is known.

The same problem can also arise with strung-together modules that do not establish a wired data bus when they are strung together, but which rather communicate independently of each other wirelessly, for example with a distributor such as a switch or gateway. Here, too, in certain circumstances, a sequence of strung-together independently communicated modules is of interest.

### SUMMARY OF THE DISCLOSURE

The present invention provides a method for forming a sequence of strung-together communication-capable modules within an arrangement. The invention further includes an arrangement of communication-capable modules that can be strung together to carry out the method.

It is an object of the present disclosure to provide a method with the following steps. First, a magnetic signal is transmitted from a first module with a predefined intensity. The intensity of the signal is increased, for example continuously or incrementally, until the signal is detected by a module which is immediately adjacent to the transmitting module, but not detected by a module which is not immediately adjacent. After the signal is detected, the module that has detected the signal emits data for its identification via a communication channel to a determining unit, which determines a sequence of the modules using the identification data.

A magnetic signal is output by the first module independent of the communication channel, the intensity of which is increased. Increasing the intensity increases the range within which the magnetic signal can be detected by a further module at a given detection sensitivity and ensures that the signal is first detected by an immediately neighboring module. This module then identifies itself as the immediate neighbor with the aid of its identification data, which is transmitted via the communication channel.

The method thus utilizes the increasing range of the magnetic signal to detect a module and then uses the communication channel to transmit the identification data. Furthermore, the communication channel can be used to coordinate the method among the various participating units, such as the modules and the determining unit.

Determining the sequence is independent of the type of communication channel and can be employed for both wired communication and wireless communication modules. Communication can also take place via a bus system or a network.

In one embodiment, an arrangement includes at least three modules, each having a communication unit and a coil for emitting and/or receiving a magnetic signal. The arrangement further includes a determining unit and is set up to perform the method described above.

A module located at an outer edge of the arrangement is preferably employed as the first module. The possibility of there being an adjacent model to each side is thus eliminated. Arrangements of this type frequently have a module at an outer edge that functions as a bus master for a data bus established among the modules. Such a module, which represents the bus master in the arrangement, is a preferred choice for the first module of the method according to the invention.

In an advantageous further embodiment of the method, after the identification data of the receiving module is outputted, the intensity of the signal is further increased until the magnetic signal is detected by a further module. This further module also outputs its identification data. The identification data can be used to continue a list of the arranged modules. The method steps can be repeated until all modules in the arrangement have been determined.

In yet another embodiment of the method, the output of the signal by the first module is terminated after the signal is detected and a further magnetic identification signal is output from the module which has output its identification data. In this way, the method can be carried out for arrangements having a large number of modules if the magnetic identification signal starting from a first module at the edge of the arrangement does not extend to the last module at the opposite edge of the arrangement. Preferably, the specified first module then no longer participates in the method and also no longer reacts to magnetic fields that are still being transmitted as part of this identification cycle.

In one configuration, to output and/or receive the magnetic signal, one coil is arranged in each module, with an axial direction of the coil being aligned in the direction in which the modules are strung-on. Preferably, the coils are positioned within the modules in such a way that all coils are arranged on a common axis when the modules are strung together. The coils are also preferably arranged on a coil core, which extends in the direction in which the modules are strung on. It is ideal for the core to be a rod-shaped core that is open on both sides, such as a ferrite core.

In one preferred embodiment, the magnetic identification signal is generated by connecting an electrical pulse of variable length to the coil. In particular, the pulse is a rectangular voltage pulse. Due to the inductivity of the coil, in the case of a rectangular voltage pulse applied to the spool, the magnetic field strength increases monotonically over time, which in a first approximation is linear, so that the signal is generated with a magnetic field strength amplitude that is dependent on the length of the voltage pulse. Thus, the range of the magnetic signal can be easily altered by varying the pulse length.

### BRIEF DESCRIPTION OF THE DRAWINGS

The invention will be explained in greater detail below using exemplary embodiments with the aid of figures. In the figures:

FIG. 1 is a perspective view of an arrangement of a number of communication-capable strung-together modules;

FIG. 2 is a side view of the arrangement according to FIG. 1;

FIG. 3 is a partial cross-section perspective view of a head module of the arrangement of FIGS. 1 and 2;

FIG. 4 is a perspective view of a module of the arrangement of FIGS. 1 and 2; and

FIG. 5 is a flow diagram of an exemplary embodiment of a method of determining a sequence of strung-together modules.

### DETAILED DESCRIPTION

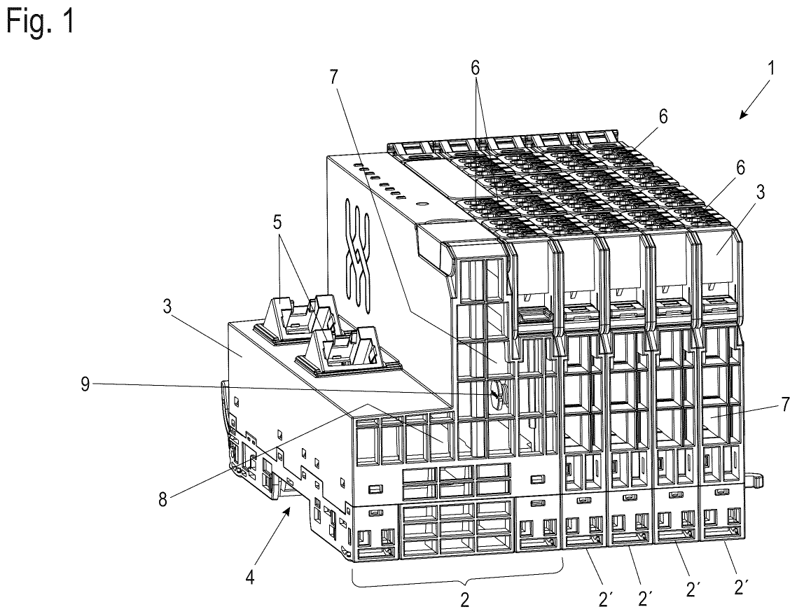

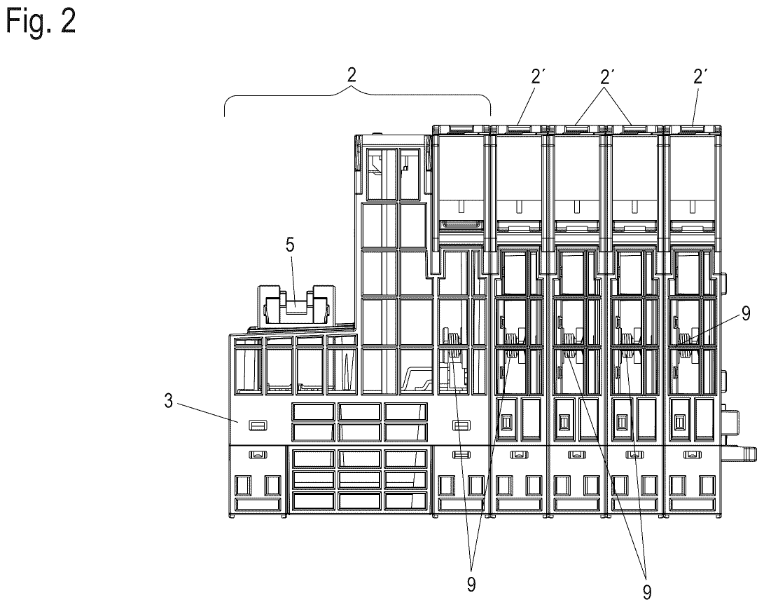

FIG. 1 shows a perspective view of an arrangement 1 of strung-together communication-capable modules 2, 2′, which form a so-called “Remote I/O” system; i.e. an input and/or output station for analog and/or digital signals which is connected to a control system and which can be positioned at a distance from it. FIG. 2 shows the arrangement of FIG. 1 in a side view.

One module 2 is a “head module” (or head station) and will hereafter also be referred to as a head module 2. The further modules 2′ are input and output modules, which may be hereafter referred to as I/O modules 2′.

All modules 2, 2′ have a housing 3 with a mounting rail receptacle 4 for latching onto a mounting rail in a switch cabinet. The lower side in FIG. 1 faces away from the user when the arrangement 1 is assembled, while the upper side FIG. 1 generally depicts a front side of the arrangement 1 and in a switch cabinet would face the user.

The head module 2 includes terminals 5 for connecting a field bus with which the head module 2 communicates with a control device (not depicted here). For example, a CAN-Bus or an Ethernet-based field bus, such as an EtherCAT bus, can be employed as a field bus terminal.

The terminals 5 are permanently installed in the housing 3. Other terminals 6 (e.g. for supplying power) are constructed in an exchangeable manner as terminal blocks which can be inserted into a corresponding recess on the upper side of the housing 3.

The I/O modules 2′ are also placed onto the mounting rail and are latched onto the head module 2 or to a neighboring I/O module 2′, which gives rise in a modular manner to the arrangement 1 of FIG. 1. The number of I/O-Modules 2′, specifically four here, is purely by way of example. On their side, the front when they are installed in a switch cabinet, the I/O modules 2′ likewise have exchangeable terminals 6. These terminals serve as a connection to sensors and/or actuators, for example of an industrial plant or a building automation.

When the modules 2, 2′ are strung together, an energy supply bus and a data bus are formed, which connect the head module 2 and the I/O modules 2′ to one another with regard to a power supply and an exchange of data. These are formed by contacts (not shown here) on the lateral faces of the modules 2, 2′ that face each other.

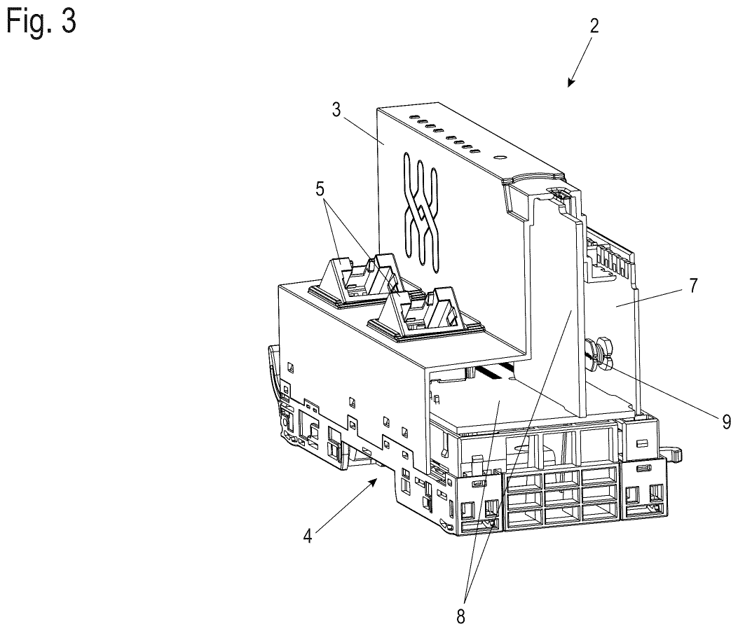

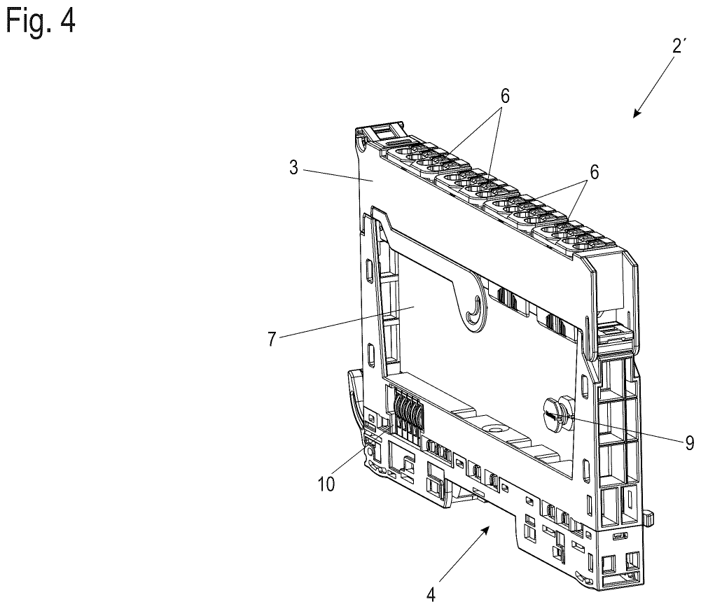

FIGS. 3 and 4 shows the internal design of the head module 2 in a partially cross-sectioned view and the internal design of one of the I/O modules 2′ in a depiction in which a housing side part is removed, respectively. As is shown, both the head module 2 and the I/O modules 2′ each have at least one printed circuit board 7, which is aligned within the housing 3 perpendicular to the mounting rail. The head module 2 has further printed circuit boards 8, which in part are also arranged in the housing 3 in a different orientation than the printed circuit board 7. In the I/O module 2′, there are data bus contacts 10.

A coil 9 is arranged at a respectively comparable position on the printed circuit board 7 in the case of each of the modules 2, 2′. By way of example, the coil 9 is constructed as a poloidal coil on a core that is open on both sides. The core can be a ferrite core, for example. When the modules 2, 2′ are strung-together into the arrangement 1, the longitudinal axes of all the coils 9 lie essentially on an axis that runs parallel to the mounting rail. For the sake of simplicity of depiction, the printed circuit boards 7, 8 are depicted without electrical or electronic components.

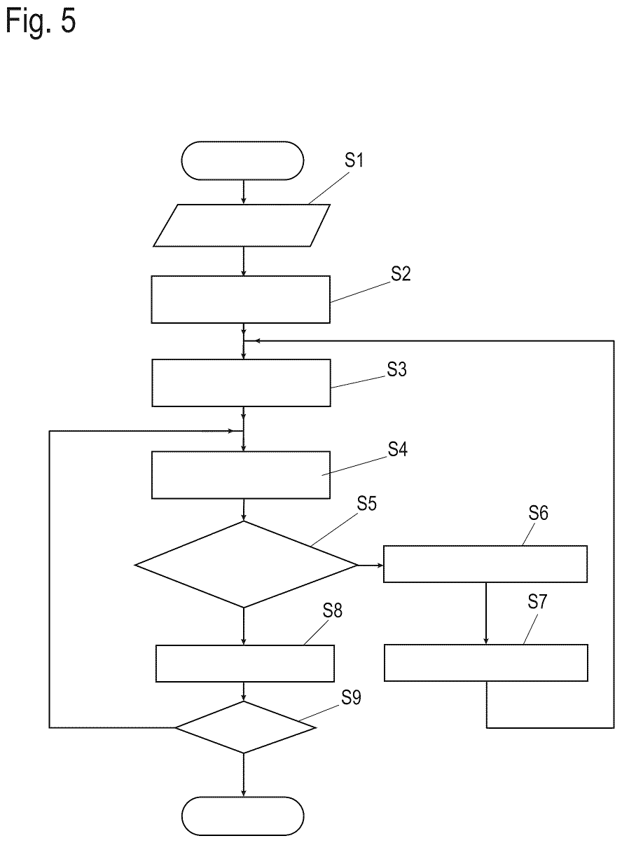

In accordance with the application, and as explained below and shown in FIG. 5, the coils 9 serve to detect a respectively neighboring module 2′ starting from the head module 2 to ascertain a sequence of the arrangement of the modules 2, 2′ with the aid of a determining unit.

The method embodiment of FIG. 5 for determining the sequence of the strung-together modules 2, 2′ is explained with reference to arrangement 1 from FIGS. 1 and 2 by way of example only. The method can also be carried out for other arrangements of strung-together modules 2, 2′. In particular, it is not necessary for the modules 2, 2′ to be connected to one another via a wired data bus, as is the case in the example of FIGS. 1 and 2. The method can also be performed with modules that are independently part of a wireless communication network. The term ‘communication channel’ used in the following explanation is to be understood in this sense as non-limiting and can be formed via a data bus or a communication network.

For the following method, it is assumed that the specified determining unit which coordinates the described method and determines the sequence of the modules 2, 2′ is arranged in the head module 2. This is also not a necessity; the method could be coordinated by a determining unit which is outside of the head station 2, as long as the head station 2 and the I/O-modules 2′ can communicate with the determining unit.

Referring to FIG. 5, in the first step S1 of the flow diagram, which is optional, a subsequent detection process is announced to the I/O modules 2′ or, if applicable, also to the head module 2. After this announcement, the modules 2, 2′ activate a detection circuit for a signal induced in the respective coil 9. If step S1 is not envisaged, the corresponding detection circuits are permanently active.

In step S2, a discrete variable n for a module number is set to an initial value, for example to the value zero: n=0.

In step S3, a variable T for a pulse length is also set to an initial value, for example the value Tmin: T=Tmin.

In step S4, a voltage pulse of pulse length T is then applied to the coil 9 by a first of the modules 2, 2′, which is assigned the module number of the initial value, which leads to the outputting of a magnetic signal of a specific amplitude. By way of example, it is assumed that the module with the initial number (n=0) is the head module 2.

If the coil 9 is subjected to a substantially rectangular voltage pulse, a current in the coil 9 increases linearly within the pulse length T in a first approximation, whereby the magnetic field strength of the built-up magnetic field also increases linearly. The longer the pulse lasts, the greater the field strength of the magnetic field built up by the coil 9.

In the following step S5, it is ascertained whether one of the I/O modules 2′ has detected the magnetic pulse output by the coil 9 of the head module 2 by the I/O modules 2′ monitoring a voltage induced in their coil 9. If the induced voltage exceeds a threshold value, the corresponding module 2′ transmits a message via a communication channel to the determining unit that a magnetic field has been recognized. In the arrangement 1 of FIGS. 1 and 2, the communication channel is the data bus established between the head module 2 and the I/O modules 2′.

If a response from one of the I/O modules 2′ is received within a predefined period of time, for example in the range of one to several milliseconds, the method branches to a next step S6. If no message is received within the predefined period of time, the method is continued in a step S8.

In step S6, identification data of this module 2′ which is sent with the message from this I/O module 2′, for example its bus address, is entered in a list in the determining unit that subsequently reflects the sequence of modules 2, 2′.

Furthermore, it can be envisaged that configuration data is sent from the determining unit to the I/O module 2′ that transmitted the message, such as a module number to be assigned to it. Advantageously, the value (n+1) is assigned as the module number.

In a following step S7, the discrete variable n is then incremented by the value 1 and the method branches back to step S3 in which the pulse width T is set back to the initial value Tmin.

The method then runs through step S4 once again, in which a magnetic pulse is output, but the magnetic pulse is no longer output by the head station 2, but rather by that I/O module 2′ that had previously detected the magnetic field. This can be done on the basis of a corresponding command that the determining unit transmits to the I/O module 2′ via the communication channel.

In the following step S5, a response is awaited from one of the as yet unrecognized I/O modules 2′. The detection circuit for an I/O module 2′ that has already been recognized, and in particular the I/O module 2′ currently emitting the magnetic pulse, is deactivated.

If in step S5, within the predefined time period, no other I/O module 2′ reports via the communication bus that it has detected a magnetic signal, the method is continued to step S8, in which the variable T for the pulse width is increased by a predefined value ΔT.

The next step S9 checks whether a predefined maximum pulse length Tmax has been reached. If the maximum pulse length Tmax is reached, the method is terminated. If the maximum pulse length Tmax is not reached, the method branches back to step S4, in which a magnetic pulse is output once again from the same I/O module 2′ as before, but this time with the pulse length T increased by the value ΔT and thus with a greater amplitude of the magnetic field.

If necessary, steps S4 to S9 are repeated until either one of the I/O modules 2′ that has not yet been determined detects the magnetic signal or until the maximum pulse length Tmax is reached. By incrementally increasing the magnetic field amplitude, the range of the magnetic pulse is increased (for a given detection sensitivity). This ensures that in each case the nearest neighboring I/O module 2 is detected as the next module 2, 2′. Thus the method determines all strung-together I/O modules 2′ in the sequence in which they are arranged starting from one side of the arrangement 1, which in this case starts from the head module 2.

What is claimed is:

1. A method of ascertaining a sequence in which at least three strung-together communication-capable modules are arranged, including the steps of:
outputting a magnetic signal with a predefined intensity from a first module;
increasing the intensity of the signal until the signal is detected by a module immediately adjacent to the outputting module but which is not detected by a module which is not immediately adjacent to the outputting module;
outputting identification data through the module which detected the magnetic signal via a communication channel to a determining unit; and
determining a sequence of the modules by the identification data.

2. The method according to claim 1, wherein after the identification data has been output by the module which has detected the magnetic signal, the intensity of the magnetic signal transmitted by the first module is increased further until the magnetic signal is detected by another module which forwards identification data to the determining unit via the communication channel.

3. The method according to claim 2, wherein the steps of outputting the magnetic signal, detecting the magnetic signal by another module and forwarding the identification data are performed repeatedly until all modules of the arrangement are determined.

4. The method according to claim 1, wherein after the identification data has been output, the module which has detected the magnetic signal outputs a magnetic signal which increases starting from the predefined intensity until the magnetic signal is detected by another module which forwards identification data to the determining unit via the communication channel.

5. The method according to claim 4, wherein the steps of outputting the magnetic signal, detecting the magnetic signal by another module and forwarding the identification data are performed repeatedly until all modules of the arrangement are determined.

6. The method according to any one of claims 1, wherein after receiving the identification data the determining unit forwards configuration data to the module which transmitted the identification data.

7. The method according to any one of claims 1, wherein the magnetic signal is generated, detected, or generated and detected by a coil which is arranged in each of the modules.

8. The method according to claim 7, wherein the magnetic signal is a magnetic pulse generated by supplying a rectangular voltage signal of a predefinable pulse width to the coil.

9. The method according to claim 8, in which the intensity of the magnetic signal is raised in that the pulse width is increased.

10. An arrangement of at least three communication-capable modules configured to be strung together, each having a coil and a determining unit, the coil for outputting, receiving, or outputting and receiving a magnetic signal, wherein the arrangement is constructed to perform the method according to claim 1.

11. The arrangement according to claim 10, wherein all coils are arranged along a common axis.

12. The arrangement according to claim 10, wherein the coils are poloidal coils.

13. The arrangement according to claim 10, wherein the coils have a ferrite core.
